(19) United States
(12) Patent Application Publication
(10) Pub. No.: US 2002/0106852 A1
(43) Pub. Date: Aug. 8, 2002

(54) Lowered channel doping with source side boron implant for deep sub 0.18 micron flash memory cell

(76) Inventors: Yue-Song He, San Jose, CA (US); Sameer Haddad, San Jose, CA (US); Richard Fastow, Cupertino, CA (US); Chi Chang, Redwood City, CA (US); Zhigang Wang, San Jose, CA (US); Sheung-Hee Park, Santa Clara, CA (US)

Correspondence Address: LAW OFFICE OF MONICA H CHOI, P O BOX 3424, DUBLIN, OH, 430160204

(21) Appl. No.: 10/012,666

(22) Filed: Oct. 30, 2001

Related U.S. Application Data
(63) Continuation-in-part of application No. 09/699,711, filed on Oct. 30, 2000.
(60) Provisional application No. 60/291,859, filed on May 18, 2001.

(51) Int. Cl. H01L 21/8234; H01L 21/8244

(52) U.S. Cl. 438/238

(57) ABSTRACT

For fabricating a flash memory cell on a semiconductor substrate, a channel dopant is implanted into the semiconductor substrate. The concentration of the channel dopant in the semiconductor substrate from the implantation process is less than about 4×10¹³/cm². A source line mask is formed over the substrate, and the source line mask has an opening to expose a source line of the semiconductor substrate. A source line dopant of a first conductivity type is implanted into the exposed source line of the semiconductor substrate. The source line mask is then removed from the semiconductor substrate. A drain mask is formed over the semiconductor substrate, and the drain mask has an opening to expose a drain region of the semiconductor substrate. A drain dopant of a second conductivity type is implanted into the exposed drain region of the semiconductor substrate. A channel region of the semiconductor substrate is disposed between the source line and the drain region. The first conductivity type of the source line dopant is opposite to the second conductivity type of the drain dopant. In addition, a conductivity type of the channel dopant is same as the first conductivity type of the source line dopant. The source line dopant that diffuses from the source line into the channel region is used to alter a threshold voltage of the flash memory cell and/or to reduce short channel effects of the flash memory cell such that a lower concentration of the channel dopant is implanted or such that the implantation of the channel dopant is even eliminated, for improved reliability and performance of the flash memory cell.

This patent application is a continuation-in-part of an earlier filed copending patent application with Ser. No. 09/699,711 filed on Oct. 30, 2000, for which priority is claimed. This earlier filed copending patent application with Ser. No. 09/699,711 is in its entirety incorporated herewith by reference.

In addition, this patent application claims priority from the provisional patent application with Ser. No. 60/291,859 filed on May 18, 2001 and with the same title and inventorship herewith. The provisional patent application with Serial No. 60/291,859 is in its entirety incorporated herewith by reference.

### TECHNICAL FIELD

The present invention generally relates to improved methods of making flash memory devices such as EEPROMs. More particularly, the present invention relates to non-volatile flash memory devices with separate implants for source and drain doping and with lowered channel doping, for enhanced speed performance and for minimized short channel effects of the flash memory cells.

### BACKGROUND ART

Semiconductor devices typically include multiple individual components formed on or within a substrate. Such devices often comprise a high density section and a low density section. For example, as illustrated in prior art FIG. 1 a, a memory device such as a flash memory 10 comprises one or more high density core regions 11 and a low density peripheral portion 12 on a single substrate 13. The high density core regions 11 typically consist of at least one M×N array of individually addressable, substantially identical floating-gate type memory cells and the low density peripheral portion 12 typically includes input/output (I/O) circuitry and circuitry for selectively addressing the individual cells (such as decoders for connecting the source, gate and drain of selected cells to predetermined voltages or impedances to effect designated operations of the cell such as programming, reading or erasing).

Prior art FIG. 1b represents a fragmentary cross section diagram of a typical memory cell 14 in the core region II of prior art FIG. 1a. Such a cell 14 typically includes the source 14b, the drain 14a and a channel 15 in a substrate or P-well 16; and the stacked gate structure 14c overlying the channel 15. The stacked gate 14c further includes a thin gate dielectric layer 17a (commonly referred to as the tunnel oxide) formed on the surface of the P-well 16. The stacked gate 14c also includes a polysilicon floating gate 17b which overlies the tunnel oxide 17a and an interpoly dielectric layer 17c overlies the floating gate 17b. The interpoly dielectric layer 17c is often a multilayer insulator such as an oxide-nitride-oxide (ONO) layer having two oxide layers sandwiching a nitride layer. Lastly, a polysilicon control gate 17d overlies the interpoly dielectric layer 17c. Each stacked gate 14c is coupled to a word line (WL0, WL1, . . . , WLn) while each drain of the drain select transistors are coupled to a bit line (BL0, BL1, . . . , BLn). The channel 15 of the cell 14 conducts current between the source 14b and the drain 14a in accordance with an electric field developed in the channel 15 by the stacked gate structure 14c. Using peripheral decoder and control circuitry, each memory cell 14 can be addressed for programming, reading or erasing functions.

In the semiconductor industry, there is a continuing trend toward higher device densities to increase circuit speed and packing densities. To achieve these high densities there has been and continues to be efforts toward scaling down the device dimensions on semiconductor wafers. Scaling in this sense refers to proportionately shrinking device structures and circuit dimensions to produce a smaller device that functions according to the parameters as a larger unscaled device. In order to accomplish such scaling, smaller and smaller features sizes are required. This includes the width and spacing of features including gate length.

The requirement of small features raises numerous concerns associated with flash memory devices, especially with regard to consistent performance and reliability. For example, as feature size decreases, such as a decrease in gate length, variations in size (such as gate length) increase. That is, it is difficult to maintain critical dimension control as the size decreases. As gate length decreases, the possibility of short channel effects increases. Nitrided tunnel oxide layers in some instances also contribute to increases in short channel effects.

A short channel effect occurs as the length between the source and drain is reduced. Short channel effects include Vt rolloff (Vt is the threshold voltage), drain induced barrier lowering (DIBL), and excess column leakage. DIBL is often caused by the application of drain voltage in short channel devices. In other words, the drain voltage causes the surface potential to be lowered.

In view of the aforementioned concerns and problems, there is an unmet need for making flash memory cells of improved quality with increased integration, and especially for sub 0.18 μm flash memory cells having reduced short channel effects.

### SUMMARY OF THE INVENTION

Accordingly, a non-volatile flash memory cell is fabricated with minimized short channel effects and enhanced speed performance by separating the implantation steps for doping the drain region and a source line and by reducing the concentration of channel dopant implanted into the channel region of the flash memory cell.

In a general aspect of the present invention, for fabricating a flash memory cell on a semiconductor substrate, a channel dopant is implanted into the semiconductor substrate. The concentration of the channel dopant in the semiconductor substrate from implantation is less than about 4×10¹³/cm². A source line mask is formed over the substrate, and the source line mask has an opening to expose a source line of the semiconductor substrate. A source line dopant of a first conductivity type is implanted into the exposed source line of the semiconductor substrate through the opening of the source line mask. The source line mask is then removed from the semiconductor substrate. A drain mask is formed over the semiconductor substrate, and the drain mask has an opening to expose a drain region of the semiconductor substrate. A drain dopant of a second conductivity type is implanted into the exposed drain region of the semiconductor substrate through the opening of the drain mask.

A channel region of the semiconductor substrate is disposed between the source line and the drain region. The first conductivity type of the source line dopant is opposite to the second conductivity type of the drain dopant. In addition, a conductivity type of the channel dopant is same as the first conductivity type of the source line dopant. According to an aspect of the present invention, the source line dopant that diffuses from the source line into the channel region is used to alter a threshold voltage of the flash memory cell or to reduce short channel effects of the flash memory cell.

In another embodiment of the present invention, implantation of the channel dopant is not performed such that the concentration of the channel dopant in the semiconductor substrate from implantation is substantially zero.

In this manner, with the lower concentration of the channel dopant, a lower threshold voltage may be achieved for the flash memory cell for enhanced speed performance. In addition, short channel effects may still be minimized with the implantation process for the source line. Furthermore, with lower concentration of the channel dopant, the breakdown voltage for the drain and source junctions may be increased for higher reliability of the flash memory cell. In addition, with the lower concentration of the channel dopant, charge carrier mobility through the channel region is less degraded for higher drive current of the flash memory cell.

These and other features and advantages of the present invention will be better understood by considering the following detailed description of the invention which is presented with the attached drawings.

### BRIEF DESCRIPTION OF DRAWINGS

FIG. 1 a is a plan view illustrating a prior art layout of a flash memory chip;

FIG. 1b is a fragmentary cross section illustrating a prior art stacked gate flash memory cell.

FIG. 2 is a cross sectional illustration of one aspect of a making a nonvolatile flash memory device in accordance with the present invention.

FIG. 3 is a cross sectional illustration of another aspect of a making a non-volatile flash memory device in accordance with the present invention.

FIG. 4 is a cross sectional illustration of yet another aspect of a making a non-volatile flash memory device in accordance with the present invention.

FIG. 5 is a cross sectional illustration of still yet another aspect of a making a non-volatile stacked flash memory device in accordance with the present invention.

FIG. 6 is a cross sectional illustration of one aspect of a non-volatile stacked flash memory device in accordance with the present invention.

FIG. 7 is a cross sectional illustration of one aspect of a non-volatile SONOS flash memory device in accordance with the present invention.

FIG. 8 is a cross sectional illustration showing implantation of a channel dopant into the substrate before formation of the gate stack in FIG. 2, according to an additional embodiment of the present invention.

FIG. 9 is a cross sectional illustration showing formation of a source region with a MDD implantation of a source region dopant after formation of the drain region in FIG. 6, according to another embodiment of the present invention.

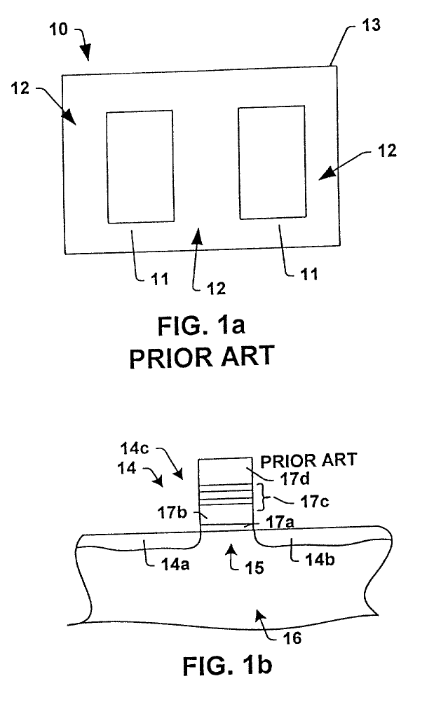

The figures referred to herein are drawn for clarity of illustration and are not necessarily drawn to scale. Elements having the same reference number in FIGS. 1, 2, 3, 4, 5, 6, 7, 8, and 9 refer to elements having similar structure and function.

### DISCLOSURE OF INVENTION

The present invention involves making non-volatile flash memory devices with different channel doping for the source and drain. As a result, non-volatile flash memory devices having reduced short channel effects are provided. The lateral diffusion after source side implant heating steps are unnecessary when making non-volatile flash memory devices in accordance with the present invention. The present invention is described with reference to the drawings wherein like reference numerals are used to refer to like elements throughout.

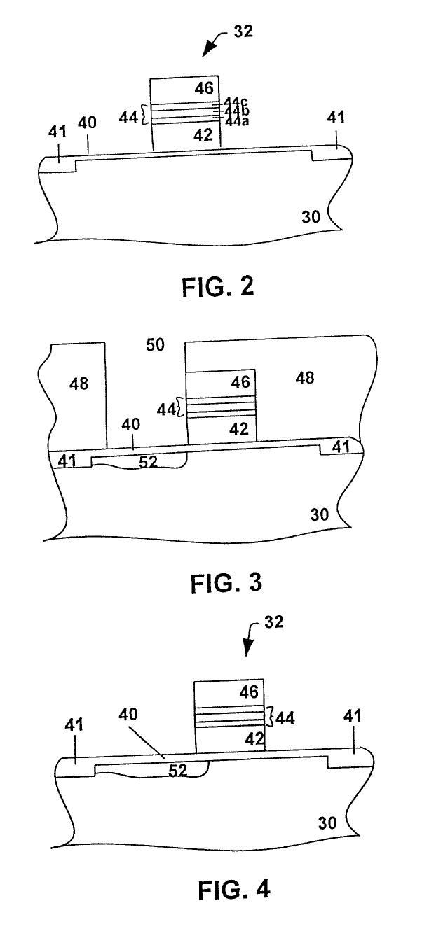

The present invention may be understood and its advantages appreciated in conjunction with the process of FIGS. 2-9, wherein like numerals represent like features throughout.

An improved semiconductor manufacturing process flow illustrating the how to make the flash memory device is described in detail in conjunction with FIGS. 2-9. This process highlights the activity in the core region of the substrate, which is where the stacked memory cells and the select gate transistors are subsequently positioned. In this connection, while the substrate contains two regions; namely, the periphery region and the core region; the core region of the substrate contains two areas; namely, the stacked memory cell area.

Referring to FIG. 2, a substrate 30 having a stacked memory cell 32 and shallow trench isolation regions 41 is provided. The stacked memory cell 32 is positioned in the stacked memory cell area of the core region of the substrate 30. The shallow trench isolation regions 41 contain an insulation material such as silicon dioxide or silicon nitride. The substrate 30 having a stacked memory cell 32 may be provided as follows, although any suitable process flow may be employed.

The substrate 30 is typically a silicon substrate optionally with various elements, regions and/or layers thereover; including metal layers, barrier layers, dielectric layers, device structures, active regions such as active silicon regions or areas, active elements and passive elements including P wells, N wells, additional polysilicon gates, wordlines, source regions, drain regions, bit lines, bases, emitters, collectors, conductive lines, conductive plugs, etc. A first oxide layer 40 is provided over at least a portion of the substrate 30 or over the entire substrate 30 using any suitable means, such as dry oxidation, wet oxidation, rapid thermal oxidation, or chemical vapor deposition (CVD).

Optionally, the first oxide layer 40 may be nitrided using a nitridation process. In some instances, employing a nitrided first oxide layer 40 contributes to short channel effects. The present invention minimizes these effects and thus enables the use of nitrided first oxide layers 40 in flash memory devices (nitrided tunnel oxide layers). The nitrided first oxide layer 40 also contributes to improved tunnel oxide reliability.

A first poly layer 42 is provided using any suitable process, such as an in situ doping process, over the first oxide layer 40. The first poly layer 42 is polysilicon or doped amorphous silicon. Polysilicon is formed using CVD techniques. The doped amorphous silicon layer is made using an in situ doping process. The first doped amorphous silicon layer 42 (also termed Poly 1) subsequently forms the floating gate of the stacked memory cell. The dopant employed to make the thin first doped amorphous silicon layer is at least one of phosphorus and arsenic.

A dielectric layer 44 is provided over at least a portion of the Poly 1 layer 42 using any suitable means. The dielectric layer 44 is preferably an ONO multilayer dielectric containing three layers; namely an oxide layer 44a, a nitride layer 44b, and another oxide layer 44c. The dielectric layer subsequently forms the interpoly dielectric layer of the stacked memory cell 32.

A second poly layer 46 is provided over at least a portion of the substrate using any suitable means. The second poly layer 46 subsequently forms the control gate of the stacked memory cell (also termed Poly 2). The second poly layer 46 is made of polysilicon or doped amorphous silicon.

Although not shown, additional layers may be provided using any suitable means over portions of the Poly 2 layer. For example, a cobalt or tungsten silicide layer may be provided over at least a portion of the Poly 2 layer 46, and a silicon oxynitride layer may be provided over the tungsten silicide layer.

Various suitable masking and etching steps are employed to form memory cells in the stacked memory cell area of the core region of the structure (the gates are defined). One or more photoresists and/or hard masks and/or the partially formed stacked memory cell (not shown) may be used as the masks. Etching is typically conducted layer by layer to maximize etch selectivity. For example, the Poly 2 layer is etched using an etch chemistry different from etching the oxide layers. Although only one stacked flash memory cell 32 is shown, a plurality of cells are formed in the core region of the structure. The structure is optionally cleaned before proceeding. The stacked flash memory cell 32 (and the SONOS type memory cell of FIG. 7) may have a width (gate length) of about 0.18 μm or smaller.

Referring to FIG. 3, a mask is formed over the structure leaving exposed the Vss line. Forming the mask 48 involves patterning a self-aligned source (SAS) mask using a photoresist or hard mask over the structure leaving the source line open 50 to further processing. That is, mask 48 has openings 50 over the substrate 30 through which the subsequently formed source lines are formed.

After the mask is formed, a source line dopant such as boron is implanted through openings 50 in the mask 48 to the exposed source line (to the exposed portion of substrate 30) forming the source side implant 52. The source line dopant may partially diffuse underneath the Poly 1 or floating gate. The source line dopant may be p type or n type, but it is preferably p type.

In one embodiment, the source line dopant is implanted at an energy from about 10 keV to about 40 keV to a dosage from about 1×10¹³ atoms/cm² to about 5×10¹⁴ atoms/cm². In another embodiment, the source line dopant is implanted at an energy from about 15 keV to about 30 keV to a dosage from about 5×10¹³ atoms/cm² to about 2×10¹⁴ atoms/cm². In yet another embodiment, the source line dopant is implanted at an energy from about 15 keV to about 25 keV to a dosage from about 5×10¹³ atoms/cm² to about 2×10¹⁴ atoms/cm². In place of or in addition to boron, phosphorus may be implanted (at the same energies and dosage levels).

Referring to FIG. 4, the source line dopant implantation is followed by removing the mask 48, and optionally cleaning the structure. It is noted that a heat treatment to promote diffusion of boron 52 under the gates (under Poly 1 gate 42) is not necessary.

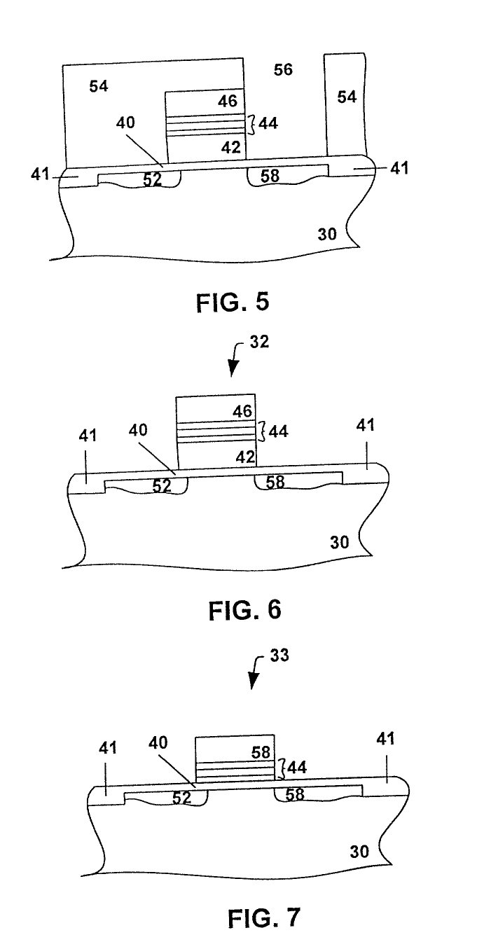

Referring to FIG. 5, a mask 54 is formed over the structure leaving exposed the drain regions of the memory cells 32 and a medium dosage drain (MDD) implant is performed forming drain 58 regions. Forming the mask 54 involves patterning a MDD mask using a photoresist or hard mask over the structure leaving the drain regions open 56 to further processing. That is, mask 54 has openings 56 over the substrate 30 through which the subsequently formed drains are formed. The MDD mask covers the entire periphery and portions of the core region that do not correspond to the drain regions. In other words, the MDD mask covers the source lines.

The MDD implant facilitates the formation of a heavy junction. The dopant may be p type or n type, but it is preferably n type. Specifically, the dopant is preferably an n+ implant, such as arsenic or phosphorus. The MDD implant dopant is preferably opposite that of the source line dopant; that is, the MDD implant is an n type when the source line dopant is a p type and the MDD implant is a p type when the source line dopant is an n type. In one embodiment, the MDD implant is performed at an energy from about 30 keV to about 60 keV to a dosage from about 5×10¹³ atoms/cm² to about 5×10¹⁵ atoms/cm². In another embodiment, the MDD implant is performed at an energy from about 35 keV to about 55 keV to a dosage from about 1×10¹⁴ atoms/cm² to about 1×10¹⁵ atoms/cm².

Referring to FIG. 6, the MDD drain side implantation is followed by removing the mask 54, and optionally cleaning the structure. A heat treatment to promote diffusion of boron 52 and the MDD implant 58 under the gates (under Poly 1 gate 42) may be performed. In one embodiment, the heat treatment involves heating the structure under an inert gas atmosphere at a temperature from about 400° C. to about 1,200° C. for a time from about 1 second to 5 minutes. Inert gases include nitrogen, helium, neon, argon, krypton, and xenon. In another embodiment, the heat treatment involves heating the structure under a temperature from about 500° C. to about 1,100° C. for a time from about 10 seconds to 3 minutes. In yet another embodiment, the heat treatment involves heating the structure under a temperature from about 600° C. to about 1,000° C. for a time from about 15 seconds to 2 minutes.

Referring to FIG. 9, then, a source side connection implant is performed by implanting a source region dopant to form a source region 64 of the flash memory cell. The source region 64 is patterned with a source region mask 60, comprised of photoresist material for example, forming an opening 62. The source region dopant is implanted into the portion of the semiconductor substrate 30 exposed through the opening 62 to form the source region 64.

The source region dopant has a conductivity type that is same as the conductivity type of the drain dopant used for performing the MDD implant for the drain region 58 as described herein. Such a source region of the flash memory cell is distinct from the source line 52 formed from implantation of the source line dopant having a conductivity type that is opposite of the conductivity type of the drain dopant. Processes for patterning the source region 64 and performing the subsequent source side connection implant for forming such a source region 64 are known to one of ordinary skill in the art of integrated circuit fabrication.

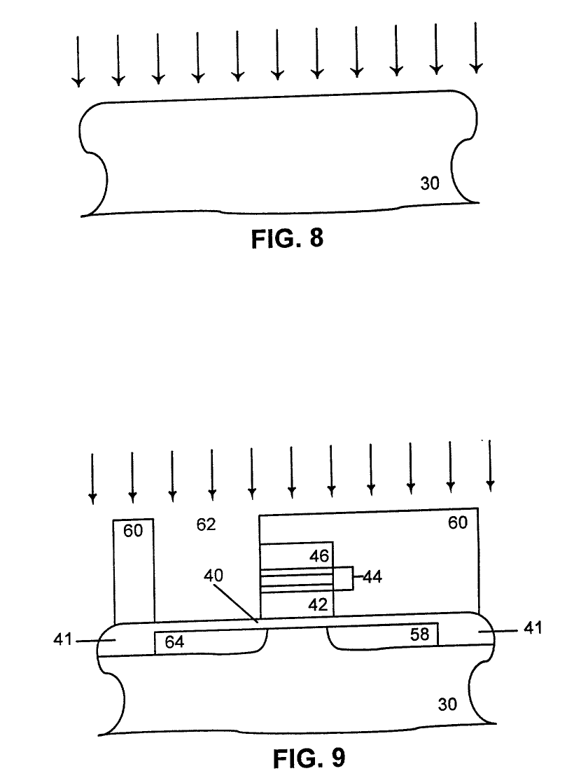

In another embodiment of the present invention, referring to FIGS. 2 and 8, before any of the structures 40, 41, 42, 44, and 46 are formed in FIG. 2, a channel dopant is implanted into the core region of the substrate 30 to dope the channel region of the flash memory cell, as illustrated in FIG. 8. Such implantation of a channel dopant, which may be comprised of a P-type dopant such as boron for example or an N-type dopant such as phosphorous for example is performed to adjust the threshold voltage of the flash memory cell or to minimize undesired short channel effects of the flash memory cell, as known to one of ordinary skill in the art of integrated circuit fabrication.

In the prior art, a channel dopant with an implantation concentration of at least 6×10¹³/cm² is used for doping the channel region of the flash memory cell. However, with such a high concentration of the channel dopant, when the channel dopant is used to minimize undesired short channel effects, the threshold voltage of the flash memory cell may be increased to degrade the speed performance of the flash memory cell. In addition, with such a high concentration of the channel dopant, charge carrier mobility may be reduced to result in lower drive current for the flash memory cell. Furthermore, with such a high concentration of the channel dopant, when the channel dopant is used to adjust the threshold voltage of the flash memory cell, the undesired short channel effects may increase or the breakdown voltage for the drain and source junctions may be decreased.

In this alternative embodiment of the present invention, referring to FIG. 2, the concentration of the channel dopant, implanted into the core region of the substrate 30 before any of the structures 40, 41, 42, 44, and 46 are formed, is decreased from the prior art range of at least 6×10¹³/cm² to be in a lower range of from about 4×10¹³/cm² to about 0/cm², in combination with using separate implantation processes for doping the drain region and the source line. Because of the separate implantation processes for doping the drain region and the source line, the process for implanting the source line of the flash memory cell (as described herein) may be used to further adjust the threshold voltage of the flash memory cell and/or to further minimize undesired short channel effects of the flash memory cell.

During the heat treatment when the semiconductor substrate 30 is heated (such as after the MDD implant for the drain region 58 as described herein), the source line dopant diffuses from the source line 52 into the channel region of the semiconductor substrate between the source line 52 and the drain region 58 and under the gate. The source line dopant within the channel region alters the threshold voltage of the flash memory cell and/or reduces the short channel effects of the flash memory cell.

In one embodiment of the invention, a channel dopant is not implanted at all, and the process for implanting the source line of the flash memory cell (as described herein) is used exclusively to adjust the threshold voltage of the flash memory cell and/or to minimize undesired short channel effects of the flash memory cell. Alternatively, a lower concentration of the channel dopant, less than about 4×10¹³/cm², is used to dope the channel region of the flash memory cell. In that case, the process for implanting the source line of the flash memory cell (as described herein) is also used to further adjust the threshold voltage of the flash memory cell and/or to further minimize undesired short channel effects of the flash memory cell. In any case, the implantation process for the source line that is separate from the implantation process for the drain region (as described herein) allows for further adjustment of the parameters of the implantation process for the source line to adjust the threshold voltage of the flash memory cell and/or to minimize undesired short channel effects of the flash memory cell.

With the lower concentration of the channel dopant, a lower threshold voltage may be achieved for the flash memory cell for enhanced speed performance. In addition, short channel effects may still be minimized with the implantation process for the source line. Furthermore, with lower concentration of the channel dopant, the breakdown voltage for the drain and source junctions may be increased for higher reliability of the flash memory cell. In addition, with the lower concentration of the channel dopant, charge carrier mobility through the channel region is less degraded for higher drive current of the flash memory cell.

In an example N-channel flash memory cell, boron is implanted as a channel dopant into the core region of the substrate 30 before any of the structures 40, 41, 42, 44, and 46 are formed to minimize short channel effects of the flash memory cell. However, such channel dopant at the prior art high concentration of at least 6×10¹³/cm² increases the threshold voltage of the N-channel flash memory cell to degrade the speed performance of the flash memory cell. In this example, the separate source line implantation process (as described herein) is used to minimize short channel effects of the flash memory cell. Thus, the concentration of boron as the channel dopant may be decreased to less than 4×10¹³/cm², or the implantation of such channel dopant may be eliminated since short channel effects are already minimized from the source line implantation process. With such decrease in the concentration of boron as the channel dopant, the threshold voltage of the flash memory cell is decreased to enhance the speed performance of the flash memory cell.

In another aspect of the present invention, the conductivity type of the channel dopant is the same as the conductivity type of the source line dopant of the source line implantation process when the source line implantation process is used to minimize short channel effects of the flash memory cell or to alter the threshold voltage of the flash memory cell. For instance, both the channel dopant and the source line dopant of the source line implantation process may be comprised of a p-type dopant when the drain dopant is an n-type dopant. For example, both the channel dopant and the source line dopant of the source line implantation process may be comprised of boron when the drain dopant is an n-type dopant, according to one embodiment of the present invention.

Various embodiments of the present invention are also applicable to SONOS (Silicon Oxide Nitride Oxide Silicon) type memory devices. Referring to FIG. 7, a SONOS type memory device 33 is shown having the source side boron implant 52 and a MDD drain side implant 58 in accordance with the present invention. The SONOS type memory device 33 is processed in the same manner as stacked flash memory cell 32 in FIGS. 2-6. Thus, FIG. 7 is analogous to FIG. 6. The present invention is applicable to both NAND and NOR type memory configurations.

Although not shown, a series of mask and etch steps (such as self aligned etch steps) are employed to form select gate transistors in the core region, high voltage transistors and low voltage transistors in the periphery region, word lines, contacts, interconnections, an encapsulating oxide film, such as tetraethylorthosilicate (TEOS), borophosphotetraethylorthosilicate (BPTEOS), phosphosilicate glass (PSG), or borophosphosilicate glass (BPSG), and the like. These steps may be conducted during and/or after formation of the memory cells in accordance with the present invention. These steps are known in the art.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including any reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

We claim:

1. A method for fabricating a flash memory cell on a semiconductor substrate, the method comprising the steps of:
implanting a channel dopant into said semiconductor substrate, wherein a concentration of said channel dopant in said semiconductor substrate from implantation is less than about 4×10¹³/cm²;
forming a source line mask over said substrate, wherein said source line mask has an opening to expose a source line of said semiconductor substrate;
implanting a source line dopant of a first conductivity type into said exposed source line of said semiconductor substrate through said opening of said source line mask;
wherein a conductivity type of said channel dopant is same as said first conductivity type of said source line dopant;
removing said source line mask from said semiconductor substrate;
forming a drain mask over said semiconductor substrate, wherein said drain mask has an opening to expose a drain region of said semiconductor substrate;
implanting a drain dopant of a second conductivity type into said exposed drain region of said semiconductor substrate through said opening of said drain mask to form a drain region of said flash memory cell;
wherein said first conductivity type of said source line dopant is opposite to said second conductivity type of said drain dopant;
wherein a channel region of said semiconductor substrate is disposed between said source line and said drain region; and
using said source line dopant that diffuses from said source line into said channel region to alter a threshold voltage of said flash memory cell or to reduce short channel effects of said flash memory cell.

2. The method of claim 1, wherein said source line dopant and said channel dopant are comprised of boron when said drain dopant is an n-type dopant.

3. The method of claim 1, wherein said step of implanting said channel dopant is not performed such that said concentration of said channel dopant in said semiconductor substrate from implantation is substantially zero.

4. The method of claim 1, further comprising the step of:
heating said semiconductor substrate such that said source line dopant diffuses into said channel region.

5. The method of claim 4, wherein said semiconductor substrate is heated to a temperature in a range of from about 400° Celsius to about 1200° Celsius.

6. The method of claim 1, wherein said source line dopant is implanted at an energy of from about 10 keV to about 40 keV with a dosage of from about 1×10¹³ atoms/cm² to about 5×10¹⁴ atoms/cm.

7. The method of claim 1, wherein said drain dopant is implanted at an energy of from about 30 keV to about 60 keV with a dosage of from about 5×10¹³ atoms/cm² to about 5×10¹⁵ atoms/cm².

8. The method of claim 1, wherein said flash memory cell comprises a first poly layer disposed on a tunnel oxide, an ONO multi-layer dielectric over said first poly layer, and a second poly layer over the ONO multi-layer dielectric.

9. The method of claim 1, wherein said flash memory cell comprises an ONO charge trapping layer, and a poly layer over the ONO charge trapping layer.

10. The method of claim 1, further comprising the step of:
implanting a source region dopant having a conductivity type that is same as the second conductivity type of said drain dopant to form a source region of said flash memory cell.

11. A flash memory cell fabricated on a semiconductor substrate, the flash memory cell comprising:
a source line formed from implantation of a source line dopant of a first conductivity type into said semiconductor substrate;
a drain region formed from implantation of a drain dopant of a second conductivity type into said semiconductor substrate;
wherein said first conductivity type of said source line dopant is opposite to said second conductivity type of said drain dopant;
a channel region disposed between said source line and said drain region, and wherein a channel dopant is implanted into said channel region such that a concentration of said channel dopant in said channel region from implantation is less than about 4×10¹³/cm²;
and wherein a conductivity type of said channel dopant is same as said first conductivity type of said source line dopant;
and wherein said source line dopant of said source line that diffuses from said source line into said channel region alters a threshold voltage of said flash memory cell or reduces short channel effects of said flash memory cell.

12. The flash memory cell of claim 11, wherein said source line dopant and said channel dopant are comprised of boron when said drain dopant is an n-type dopant.

13. The flash memory cell of claim 11, wherein said implantation of said channel dopant is not performed such that said concentration of said channel dopant in said semiconductor substrate from implantation is substantially zero.

14. The flash memory cell of claim 11, wherein said semiconductor substrate is heated such that said source line dopant diffuses into said channel region.

15. The flash memory cell of claim 11, wherein said source line dopant is implanted at an energy of from about 10 keV to about 40 keV with a dosage of from about 1×10¹³ atoms/cm² to about 5×10¹⁴ atoms/cm².

16. The flash memory cell of claim 11, wherein said drain dopant is implanted at an energy of from about 30 keV to about 60 keV with a dosage of from about 5×10¹³ atoms/cm² to about 5×10¹⁵ atoms/cm².

17. The flash memory cell of claim 11, further comprising a first poly layer disposed on a tunnel oxide, an ONO multi-layer dielectric over said first poly layer, and a second poly layer over the ONO multi-layer dielectric.

18. The flash memory cell of claim 11, further comprising an ONO charge trapping layer, and a poly layer over the ONO charge trapping layer.

19. The flash memory cell of claim 11, further comprising:
a source region formed by implanting a source region dopant having a conductivity type that is same as the second conductivity type of said drain dopant.
